(19) United States
(12) Patent Application Publication
(10) Pub. No.: US 2008/0088379 A1
(43) Pub. Date: Apr. 17, 2008

(54) Current device and method for phase-locked loop

(75) Inventor: Yi-Kuang Chen, Tai Chung City (TW)

Correspondence Address: BIRCH STEWART KOLASCH & BIRCH, PO BOX 747, FALLS CHURCH, VA, 22040-0747, US

(73) Assignee: REALTEK SEMICONDUCTOR CORP.

(21) Appl. No.: 11/907,695

(22) Filed: Oct. 16, 2007

(30) Foreign Application Priority Data
Oct. 17, 2006 (TW) 095138153

(51) Int. Cl. H03K 3/03; G05F 3/16

(52) U.S. Cl. 331/57; 327/536; 327/543

(57) ABSTRACT

A current device capable of process, voltage and temperature compensation for phase-locked loop (PLL) is disclosed. The current device can adjust the central frequency of oscillation of a voltage-controlled oscillator (VCO), making a compensated central oscillating frequency not affected by all process, voltage and temperature (PVT) variations. Meanwhile, the VCO having lower K_{VCO} can operate in the same range of operating frequencies. Further, the current device of the invention can also be applied to a charge pump circuit, causing the charge pump current I_{cp} to vary according to K_{VCO} and therefore making the product of (I_{cp}*K_{VCO}) substantially independent of the PVT conditions.

### BACKGROUND OF THE INVENTION

1. Field of the Invention

The invention relates to current devices, and more particularly, to a current device for phase-locked loops.

2. Description of the Related Art

FIG. 1 is a block diagram of a conventional phase-locked loop. Referring to FIG. 1, a phase-locked loop (PLL) 100 includes a phase detector 102, a charge pump 104, a low-pass filter (LPF) 106, a voltage-controlled oscillator (VCO) 110 and a frequency divider 108. At start-up, the phase detector 102 compares the phase difference between a reference clock and a feedback clock and supplies two signals UP, DN, corresponding to the phase difference, to the charge pump 104. Based on the signals UP, DN, the charge pump 104 outputs a control voltage V_{ctrl} to the input terminal of the VCO 110. The charge pump 104 includes two switches that are driven by two signals UP, DN. By means of controlling two signals UP, DN, the charge pump 104 injects the charge into or out of a resistor and a capacitor (not shown) in the LPF 106. Then, the VCO 110 generates an output clock in response to the control voltage V_{ctrl} generated by the charge pump's charging or discharging the LPF 106. Next, the frequency divider 108 divides down the output clock and then generates the feedback clock to be provided to the phase detector 102 for the phase difference comparison. As such, the operation goes on until the frequency and the phase of the reference clock are substantially equivalent to those of the feedback clock; consequently, the phase-locked loop completes the locked operation.

Regarding the related applications, such as frequency synthesizers and clock and data recovery circuits, the VCO and the charge pump are more easily affected by external environments, such as process, voltage and temperature (PVT) variations. A VCO gain is expressed as K_{VCO}=dω/dv=df/dv (where ω denotes the angular frequency, f denotes the operating frequency and v denotes the voltage), which is a reference index. Operation of a VCO having high K_{VCO} in a PLL is operable under a wider range of PVT conditions while operation of a VCO having low K_{VCO} in a PLL causes the PLL to have low noise sensitivity.

U.S. Pat. No. 5,064,907 and U.S. Pat. No. 6,326,855 describe two VCOs, employing an open loop compensation and compensating a voltage-to-current converter, where a compensating current is basically proportional to absolute temperature. Besides, a VCO with temperature compensation is disclosed by Hyung-Rok Lee et al, “A 1.2-V-only 900 mW 10 gb Ethernet transceiver and XAUI interface with robust VCO tuning technique,” JSSC, VOL. 40, No. 11, November 2005.

On the other hand, since a VCO with only one frequency-voltage characteristic curve having large K_{VCO} has high noise sensitivity, many VCOs with multiple frequency-voltage characteristic curves each having low K_{VCO} have been developed. FIG. 2A is a graph of a set of frequency-voltage characteristic curves of a conventional multi-range VCO with two inputs. Nonis et al, “Modeling, Design and Characterization of a New Low-Jitter Analog Dual Tuning LC-VCO PLL Architecture,” IEEE Journal of Solid-state Circuits, VOL. 40, No. 6, June 2005, discloses a continuous time dual-loop tuning applied to a VCO with two inputs, whose K_{VCO,f} is much lower than K_{VCO,S} of a standard VCO with one input. In operation of a PLL including the VCO with two inputs, coarse control is achieved by varying the voltage V_{C} appropriately to cause the VCO to operate with a selected “best” one of the available characteristic curves. Next, fine control is achieved by making (V_{finep}−V_{finen}) close to the reference voltage (V_{refp}−V_{refn}). This voltage (V_{finep}−V_{finen}) has been chosen in order to keep the VCO characteristic in the linear region (i.e., where K_{VCO,f} is almost constant) and have the same output frequency range as in the standard PLLs do.

FIG. 2B is a graph of a set of frequency-voltage characteristic curves of another conventional multi-range VCO using a discrete time dual-loop tuning. Referring to FIG. 2B, V_{L} is a minimum control voltage and V_{H} is a maximum control voltage. Each frequency-voltage characteristic curve is measured at the same process corner and there is sufficient frequency overlap between the frequency-voltage characteristic curves. In operation of a PLL including the VCO, coarse control is achieved by causing the VCO to operate with a selected “best” one of the available characteristic curves. Fine control is achieved by causing the VCO to operate at a “best” operating point along the selected frequency-voltage characteristic curve.

FIG. 2C is a graph of a set of frequency-voltage characteristic curves of a conventional single-band VCO measured at different process corners and different temperatures. Referring to FIG. 2C, the curve measured at a low temperature has large K_{VCO} (or large slope), whereas the curve measured at a high temperature has low K_{VCO} (or low slope). Therefore, to the single-band VCO, a same operating frequency is mapped to a smaller control voltage based on a frequency-voltage curve having large K_{VCO} and to a larger control voltage based on a frequency-voltage curve having low K_{VCO}.

Daily et, al, “A Low-Power Multiplying DLL for Low-Jitter Multigigahertz Clock Generation in Highly Integrated Digital Chips,” IEEE Journal of Solid-state Circuits, VOL. 37, No. 12, December 2002, discloses a adaptive-biased charge pump used to compensate for the K_{VCO} variations across different process corner in PLLs. According to the control voltage V_{cntl} of the VCO, the charge pump correspondingly generates a charge pump current Icp, causing the product of (K_{VCO}×I_{cp}) to be independent of PVT variations. To maintain the same output operating frequency, the VCO having lower K_{VCO} (lower slope) needs a larger control voltage (as shown in FIG. 2C), and vice versa. Thus, according to the control voltage V_{ctrl}, the charge pump correspondingly generates a charge pump current to compensate for the K_{VCO} variations.

### SUMMARY OF THE INVENTION

In view of the above-mentioned problems, an object of the invention is to provide a current device for PLLs, capable of actively generating a corresponding compensating voltage or compensating current in accordance with the K_{VCO} variations.

To achieve the above-mentioned object, the current device comprises: a compensating voltage generator and a current output unit. The compensating voltage generator used to generate a compensating voltage comprises: a first transistor for receiving a reference current and generating the compensating voltage; and, a compensating unit coupled to the first transistor for compensating the compensating voltage. The current output unit comprises at least one second transistor which is used to output a first output current according to the compensating voltage. Wherein, the second transistor and the first transistor form a current mirror.

Further scope of the applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus are not limitative of the present invention, and wherein:

FIG. 1 is a block diagram of a conventional phase-locked loop.

FIG. 2A is a graph of a set of frequency-voltage characteristic curves of a conventional multi-range VCO with two inputs.

FIG. 2B is a graph of a set of frequency-voltage characteristic curves of another conventional multi-range VCO using a discrete time dual-loop tuning.

FIG. 2C is a graph of a set of frequency-voltage characteristic curves of a conventional single-band VCO measured at different process corners and different temperatures.

FIG. 3 is a block diagram of a VCO according to an embodiment of the invention.

FIG. 4A shows details of a preferred embodiment of the bias voltage and compensating voltage generating circuit of FIG. 3.

FIG. 4B shows details of a preferred embodiment of the delay cell of FIG. 3.

FIG. 5 illustrates a set of frequency-voltage characteristic curves of the VCO measured at different process corners and different control voltages according to the invention.

FIG. 6 shows a block diagram of a preferred embodiment of a charge pump.

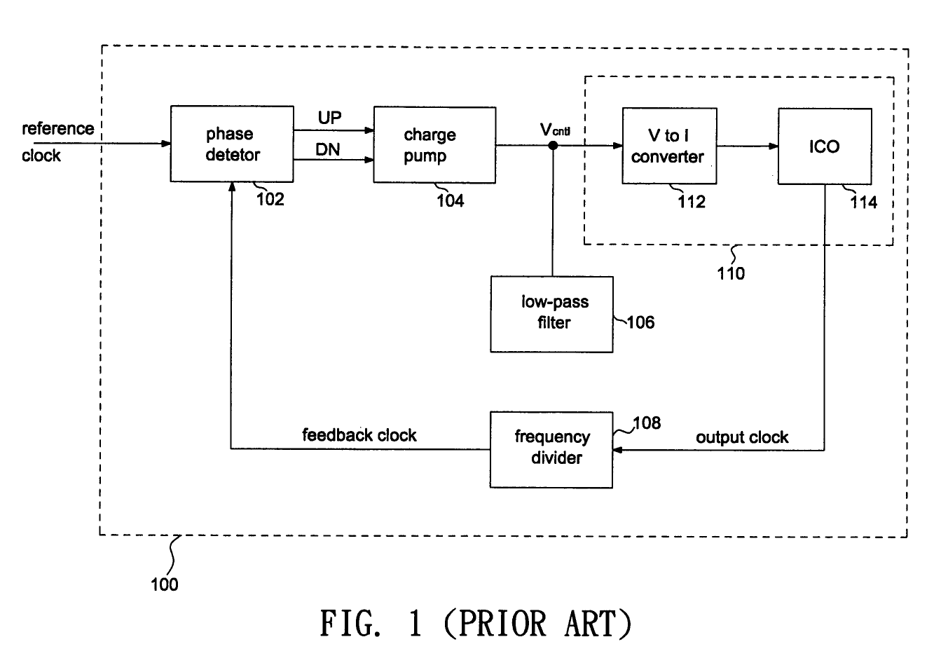

### DETAILED DESCRIPTION OF THE INVENTION

The current device and method for PLL of the invention will be described with reference to the accompanying drawings.

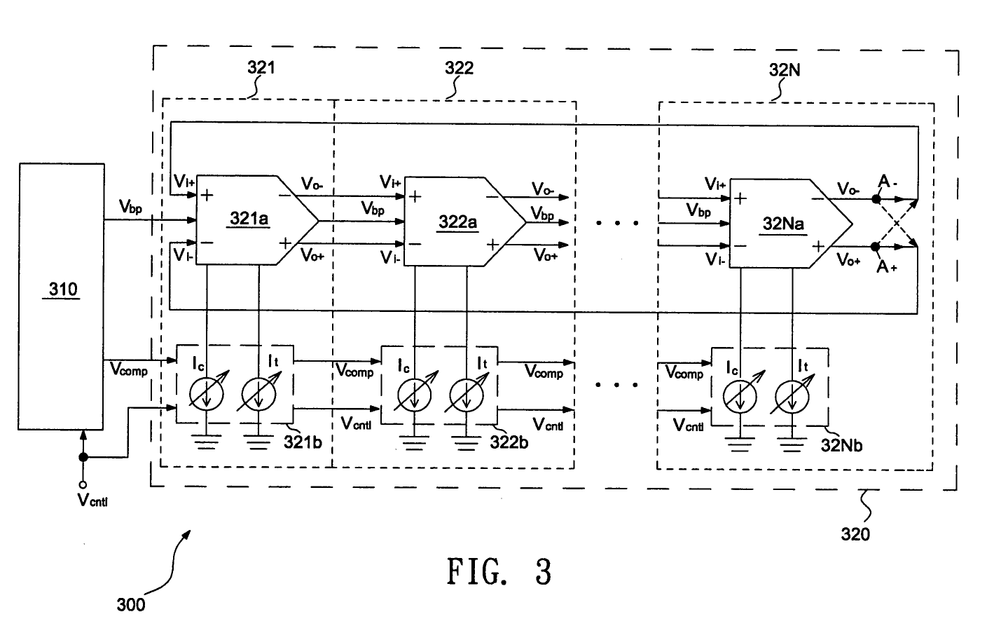

FIG. 3 is a block diagram of a VCO according to an embodiment of the invention. Referring to FIG. 3, a VCO 300 includes a bias voltage and compensating voltage generating circuit 310 and a N-stage (where N is a positive integer and greater than one) ring oscillator 320. The ring oscillator 320 includes N delay cells 321˜32N, each of which includes a current-controlled delay unit 321a˜32Na and a voltage-controlled current source 321b˜32Nb.

The bias voltage and compensating voltage generating circuit 310 generates a bias voltage V_{bp} to be provided to all delay units 321a˜32Na and a compensating voltage V_{comp} to be provided to all voltage-controlled current source 321b˜32Nb. According to the delay time T of each delay cell and a pre-defined frequency f_{OSC} of oscillation, a circuit designer connects N delay cells in series to form the N-stage ring oscillator, whose frequency of oscillation is expressed as f_{OSC}=1/(N×T). Here, the greater the number N or the delay time T of the ring oscillator is, the lower the frequency f_{OSC} of oscillation becomes. In this embodiment, the number N can be even or odd since the ring oscillator is differential. If the number N is even, two output terminals A+, A− of one of the N delay cells has to be inverted and then connected to the input terminals of the next stage, therefore the dotted line representation in FIG. 3. If the number N is odd, two output terminals A+, A− of the N delay cells need not be inverted, therefore the solid line representation in FIG. 3.

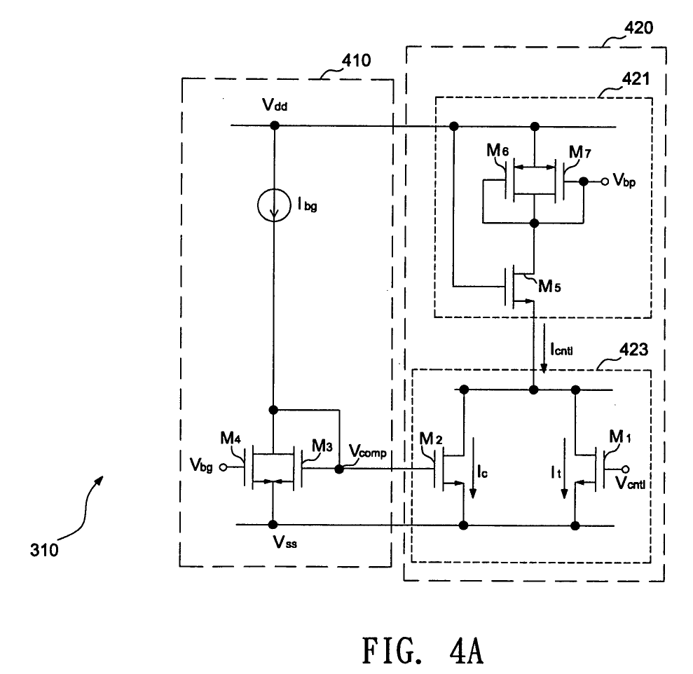

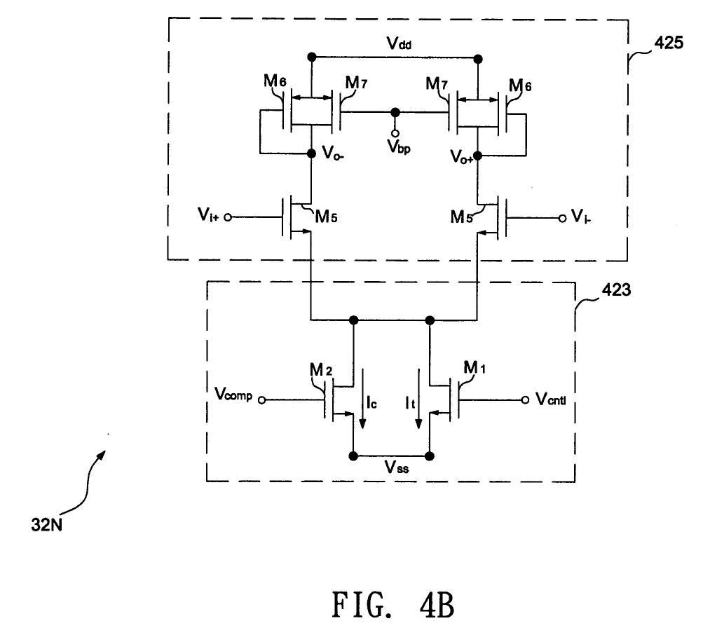

FIG. 4A shows details of a preferred embodiment of the bias voltage and compensating voltage generating circuit of FIG. 3. Referring to FIG. 4A, the bias voltage and compensating voltage generating circuit 310 includes a compensating voltage generator 410 and a half-replica bias-voltage generator 420. The compensating voltage generator 410 is used to generate a compensating voltage V_{comp}. The half-replica bias-voltage generator 420 includes a half-replica delay unit 421 and a V-to-I converter 423. Here, the compensating voltage generator 410 and the V-to-I converter 423 constitute an embodiment of the current device. The V-to-I converter 423, including two NMOS transistors M₁, M₂, generates a control current I_{cntl} (=Iₜ+I_{c}) according to a control voltage V_{cntl} (provided by a charge pump) and the compensating voltage V_{comp}. The half-replica delay unit 421, including two PMOS transistors M₆, M₇ and a NMOS transistor M₅, generates a bias voltage V_{bp} according to the control current I_{cntl}.

Assuming that the voltage V_{bp} and the current I_{bg} are fixed and independent of the PVT variations, a compensating transistor M₄ is connected in parallel with a transistor M₃ to track a transistor M₁ which is varied depending on the PVT variations. As the modulated current Iₜ flowing through the transistor M₁ decreases due to the PVT variations (K_{VCO}, gₘ 1 decreasing), the current I₄ (not shown) flowing through the transistor M₄ decreases as well (gₘ 4 decreasing). At this moment, the current I_{bg} is fixed, so the current I₃ flowing through the transistor M₃ increases, making the compensating voltage V_{comp} increasing. As a result of the increasing compensating voltage V_{comp}, the compensating current I_{C} flowing through the transistor M₂ also increases (transistors M₃, M₂ forming a current mirror circuit), finally a fixed control current I_{cntl} (=Iₜ+I_{c}). Accordingly, as the PVT conditions vary, the current I_{C} is actively varied depending on the current Iₜ variations (or the conductance gₘ 1 variations). The current mirror M₃, M₂ amplifies the current difference between the current I_{bg} and the output current I₄ of the transistor M₄ to generate the compensating current I_{C}. Here, the compensating current following through the transistor M₁ is expressed as I_{C}=I_{bg}−V_{bg}*gₘ 4*gₘ 2/gₘ 3, where the variation value (gₘ 4*gₘ 2/gₘ 3) will track the conductance gₘ 1 variations in the transistor M₁ (due to PVT variations or other environmental change). Besides, a open-loop structure has been employed to implement the circuit for generating the compensating current I_{C}.

On the other hand, assuming that each of all signals varied according to the PVT variations can be regarded as a combination of a constant signal and a variable signal, for example, the current flowing through the transistor M₁ can be expressed as Iₜ=I_{const1}+Iᵥₐᵣ₁=I_{const1}+gₘ 1*V_{cntl} and the current flowing through the transistor M₂ can be expressed as I_{C}=I_{const2}−Iᵥₐᵣ₂=I_{const2}+gₘ 2*V_{const}. Accordingly, the control current can be expressed as I_{cntl}=I_{C}+Iₜ=(I_{const1}+I_{const2})+(Iᵥₐᵣ₁−Iᵥₐᵣ₂)=(I_{const1}+I_{const2})+(gₘ 1−α*gₘ 2)*V_{cntl}, where V_{const}=α*V_{cntl}.

Moreover, a current I_{bg} and a voltage V_{bg}, generated by a bandgap voltage reference circuit, are regarded as the current I_{cont2} and the voltage V_{const}, respectively. By means of selecting a proper parameter α, the variable signals can be removed (i.e., (Iᵥₐᵣ₁−Iᵥₐᵣ₂)=0) and only the constant signals (=(I_{const1}+I_{const2})) are left. Thus, the control current I_{cntl} is fixed as long as V_{bg}=V_{cntl}. On the other hand, the output current I₄ of the transistor M₄ tracks the current Iₜ variations, so the currents I₄, Iₜ vary towards the same direction (e.g., the current I₄ getting greater if the current Iₜ increases). At this point, since the current I_{bg} is fixed, the output current I₃ of the transistor M₃ and the output current I₃ of the transistor M₄ vary towards the opposite directions. Then, due to the current mirror M₃, M₂, the compensating current I_{C} and the output current I₃ vary towards the same direction as well (I₃=I_{C} if the transistors M₃, M₂ are identical), and finally the compensating current I_{C} and the current Iₜ vary towards the opposite directions.

FIG. 4B shows details of a preferred embodiment of the delay cell of FIG. 3. Referring to FIG. 4B, each delay cell (321˜32N) includes a current-controlled delay unit 425 and a V-to-I converter 423. Likewise, the V-to-I converter 423 receives the control voltage V_{cntl} generated by the charge pump and the compensating voltage V_{comp} generated by the compensating voltage generator 410 in order to generate the control current I_{cntl} (=Iₜ+I_{c}). By comparison with the half-replica delay unit 421 of FIG. 4A, the half-replica delay unit 421 is merely a half circuit of the delay unit 425. According to the control current I_{cntl} and the bias voltage V_{bp}, the delay unit 425 inverts the input clock signals at two input terminals Vᵢ₊, V₁₋ to generate delayed clock signals via the two output terminals Vₒ₊, Vₒ₋. The V-to-I converter 423 and the compensating voltage generator 410 constitute an embodiment of the current device, whose operations and compensation algorithm have been discussed above and therefore will not be described herein.

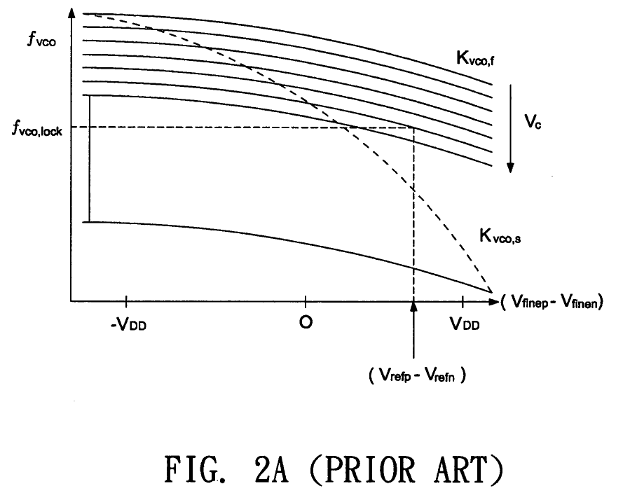

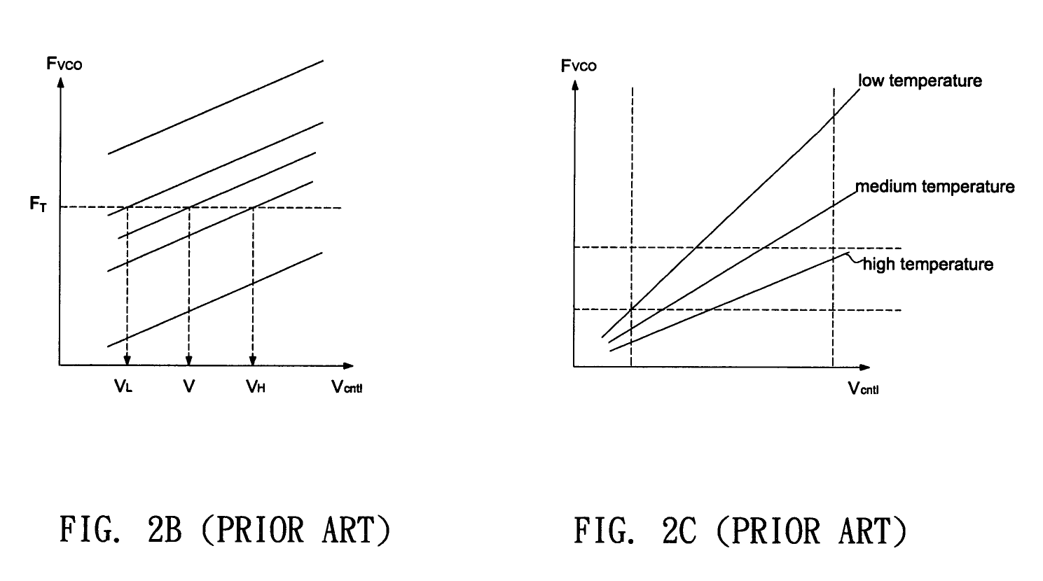

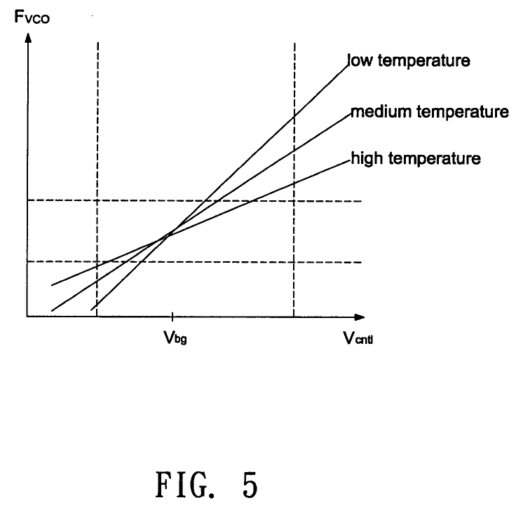

FIG. 5 illustrates a set of frequency-voltage characteristic curves of the VCO measured at different process corners and different control voltages according to the invention. According to the embodiment of the invention, the VCO 300 makes use of the structure of the compensating voltage generator 410 to compensate both the V-to-I converter 423 and the current-controlled delay unit 425. At start-up, the current I_{bg} and the voltage V_{bg} are respectively set to a fixed value (such as V_{bg}=0.45V, I_{bg}=70 μA). At different process corners and different PVT conditions, the compensating voltage generator 410 generates a corresponding compensating voltage V_{comp} and the transistor M₂ generates a corresponding compensating current I_{c}, thereby adjusting the central frequency of oscillation of each frequency-voltage characteristic curve. This causes the central frequency of oscillation of each frequency-voltage characteristic curve to intersect nearly at the same point, around V_{cntl}=V_{bg}=0.45V (as shown in FIG. 5). By comparison with FIG. 2C, we can observe that three central frequencies of three frequency-voltage characteristic curve have been adjusted or moved indeed. While the control voltage V_{cntl} is equal to the voltage V_{bg}, the control current I_{cnrl} is nearly fixed, causing the central frequency of oscillation of each frequency-voltage characteristic curve to intersect nearly at the same point (V_{cntl}=V_{bg}). Besides, the central frequency of oscillation of each frequency-voltage characteristic curve does not vary according to the PVT variations and therefore, the VCO 300 having lower K_{VCO} can operate in the same range of operating frequencies or a main range of frequencies. Note that the actual values of I_{bg} and V_{bg} are adjustable according to the circuit designer's requirements of the central frequency of oscillation, and thus are not limited to V_{bg}=0.45V, I_{bg}=70 μA.

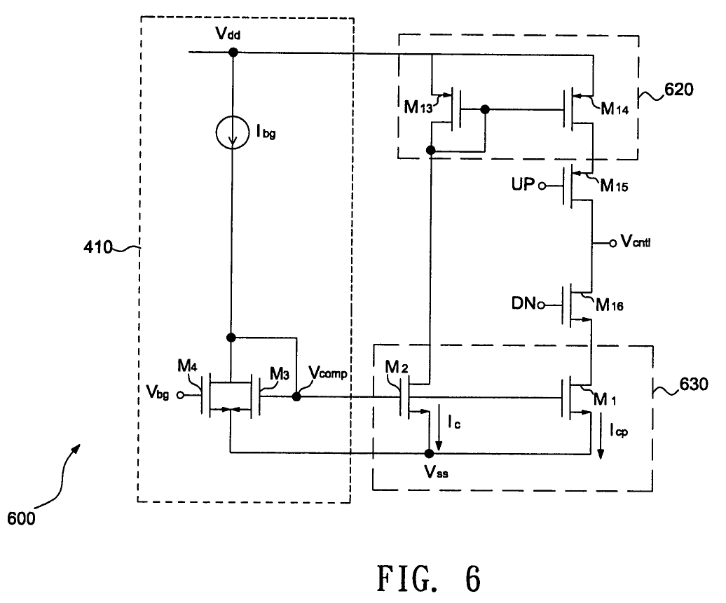

FIG. 6 shows a block diagram of a preferred embodiment of a charge pump. Referring to FIG. 6, the amount of a charge pump current I_{cp} is adjustable according to different K_{VCO}, thus maintaining a fixed product of (I_{cp}*K_{VCO}) and adjusting the amount of the control voltage V_{cntl}. A charge pump 600 includes a compensating voltage generator 410, a V-to-I converter 630, two transistors M₁₅, M₁₆ and a current mirror 620. Here, transistors M₁₅, M₁₆, acting as two switches driven by two control signals UP, DN, control a charge current I_{cp} to charge and a discharge current I₁₄ (flowing through the transistor M₁₄) to discharge the output terminal of the charge pump, respectively.

As the PVT condition varies (assuming that the temperature increases and both K_{VCO} and gₘ 4 decrease), the current I₄ (not shown) flowing through the transistor M₄ decreases. At this moment, the current I_{bg} is fixed, so the current I₃ (not shown) flowing through the transistor M₃ increases. This causes the compensating voltage V_{comp} to increase and then the currents I_{c}, I_{cp} increase as well (because the transistors M₃, M₂, M₁ form a current mirror circuit). Consequently, the current I₃, I₁₄ respectively flowing through M₁₃, M₁₄ increase simultaneously, therefore keeping the product of (I_{cp}*K_{VCO}) (i.e., the open-loop gain of the PLL) nearly fixed. Different from the prior art that generates a corresponding charge pump current according to the control voltage (V_{cntl}) the charge pump of the invention adjusts the charge pump current I_{cp} according to the K_{VCO} (or gₘ 4) variations, thereby adjusting the control voltage V_{cntl}. Thus, the charge pump of the invention is suitable for not only a single-band VCO but also a multi-range VCO. The product of I_{cp}*K_{VCO} can be derived as follows:

$$\begin{matrix}{I}_{cp} * {K}_{VCO} = ( {I}_{cp , const} + Δ {I}_{cp} ) * ( {K}_{VCO , const} - Δ {K}_{VCO} ) \\ = {I}_{cp , const} * {K}_{VCO , const} + {K}_{VCO , const} * Δ {I}_{cp} - \\ Δ {K}_{VCO} * {I}_{cp , const} - Δ {K}_{VCO} * Δ {I}_{cp}\end{matrix}$$

Since gₘ 4 tracks the K_{VCO} variations, the result of (K_{VCO,const}*ΔI_{cp}−ΔK_{VCO}*I_{cp,const}) is almost equal to zero. Further, the product of (A K_{VCO}*ΔI_{cp}) is relatively smaller than that of (I_{cp,const}*K_{VCO,const}), so the product of (I_{cp}*K_{VCO}) can be regarded as a constant.

The invention provides the current device and method thereof, which can be applied to either of a VCO and a charge pump, or even both according to the circuit designer's needs. While the invention is applied to a VCO, the central frequency of oscillation of the VCO will be compensated; while the invention is applied to a charge pump, the current I_{cp} will be compensated; while the invention is applied to both of the VCO and the charge pump, the product of (I_{cp}*K_{VCO}) will be compensated, maintaining a fixed product of (I_{cp}*K_{VCO}). The invention achieves a significant reliable compensation effect based on a simple circuit design and a low hardware cost.

It is noticed that each of transistors described in the aforementioned embodiment includes gate, drain and source terminals, their connection in each embodiment has been clearly shown in the corresponded figurations, and thus omitted in the description for diminishing the tautology.

While certain exemplary embodiments have been described and shown in the accompanying drawings, it is to be understood that such embodiments are merely illustrative of and not restrictive on the broad invention, and that this invention should not be limited to the specific construction and arrangement shown and described, since various other modifications may occur to those ordinarily skilled in the art.

What is claimed is:

1. A current device, comprising:
a compensating voltage generator for generating a compensating voltage, the compensating voltage generator comprising:
a first transistor for receiving a reference current and generating the compensating voltage; and
a compensating unit coupled to the first transistor for compensating the compensating voltage; and
a current output unit comprising at least one second transistor, wherein the second transistor is used to output a first output current according to the compensating voltage;
wherein the second transistor and the first transistor form a current mirror.

2. The current device according to claim 1, wherein the compensating unit comprises:
a compensating transistor for receiving a reference voltage, wherein the compensating transistor and the first transistor form a parallel connection.

3. The current device according to claim 1, wherein the current output unit further comprises:
a third transistor for outputting a second output current according to the compensating voltage, wherein the third transistor and the first transistor form a current mirror.

4. The current device according to claim 3, which is applied to a charge pump circuit.

5. The current device according to claim 4, wherein the first output current acts as a charge current of the charge pump circuit and the second output current acts as a discharge current of the charge pump current.

6. The current device according to claim 1, wherein the current output unit comprises:
a third transistor for receiving a control voltage and generating a second output current.

7. The current device according to claim 6, wherein the compensating unit comprises:
a compensating transistor for receiving a reference voltage, wherein the compensating transistor and the first transistor form a parallel connection.

8. The current device according to claim 7, which is applied to a voltage-controlled oscillator.

9. The current device according to claim 8, wherein the first output current and the second output current are used to control an frequency of oscillation of a clock signal generated by the voltage-controlled oscillator.

10. The current device according to claim 9, wherein a central frequency of oscillation of the clock signal is not affected by process, voltage, and temperature variations while the control voltage is substantially equivalent to the reference voltage.

11. The current device according to claim 1, which is applied to a phase-locked loop.

12. A voltage-controlled oscillator, comprising:
a compensating voltage generator for generating a compensating voltage, the compensating voltage generator comprising:
a first transistor for receiving a reference current and generating the compensating voltage; and
a compensating unit coupled to the first transistor for compensating the compensating voltage;
a voltage-controlled current source for generating a control current according to the compensating voltage and a control voltage; and
a delay unit for delaying a clock signal and generating a delayed clock signal according to the control current.

13. The voltage-controlled oscillator according to claim 12, wherein the compensating unit comprises:
a compensating transistor for receiving a reference voltage, wherein the compensating transistor and the first transistor form a parallel connection.

14. The voltage-controlled oscillator according to claim 12, wherein the voltage-controlled current source comprises:
a second transistor for generating a compensating current according to the compensating voltage; and
a control transistor for generating an adjusting current according to the control voltage;
wherein a sum of the compensating current and the adjusting current is substantially equivalent to the control current.

15. The voltage-controlled oscillator according to claim 12, wherein a central frequency of oscillation of the clock signal is not affected by process, voltage, and temperature variations while the control voltage is substantially equivalent to the reference voltage.

16. The voltage-controlled oscillator according to claim 12, wherein the delay unit is a differential delay unit.

17. The voltage-controlled oscillator according to claim 12, which is applied to a phase-locked loop.

18. A charge pump, comprising:
a compensating voltage generator for generating a compensating voltage, the compensating voltage generator comprising:
a first transistor for receiving a reference current and generating the compensating voltage; and
a compensating unit coupled to the first transistor for compensating the compensating voltage;
a current output unit for generating a charge current and a discharge current according to the compensating voltage, wherein the current output unit and the first transistor form a current mirror; and
a switch unit coupled to the current output unit for controlling the charge current to charge and the discharge current to discharge an output terminal of the charge pump according to an input control signal.

19. The charge pump according to claim 18, wherein the compensating unit comprises:
a compensating transistor for receiving a reference voltage, wherein the compensating transistor and the first transistor form a parallel connection.

20. The charge pump according to claim 18, which is applied to a phase-locked loop.
